(19) United States
(12) Patent Application Publication
(10) Pub. No.: US 2008/0111144 A1
(43) Pub. Date: May 15, 2008

(54) LIGHT EMITTING DIODE AND LASER DIODE USING N-FACE GaN, InN, AND AlN AND THEIR ALLOYS

(75) Inventors: Nicholas A. Fichtenbaum, Goleta, CA (US); Umesh K. Mishra, Montecito, CA (US); Stacia Keller, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/940,856

(22) Filed: Nov. 15, 2007

Related U.S. Application Data
(60) Provisional application No. 60/866,019, filed on Nov. 15, 2006.
(60) Provisional application No. 60/866,035, filed on Nov. 15, 2006.
(60) Provisional application No. 60/908,904, filed on Mar. 29, 2007.
(60) Provisional application No. 60/908,917, filed on Mar. 29, 2007.
(60) Provisional application No. 60/908,919, filed on Mar. 29, 2007.
(60) Provisional application No. 60/940,052, filed on May 24, 2007.

(51) Int. Cl. H01L 33/00; H01L 21/04

(52) U.S. Cl. 257/96; 438/47; 257/E33.023; 257/E21.04

(57) ABSTRACT

The present invention allows the growth of InGaN with greater compositions of Indium than traditionally available now, which pushes LED and LD wavelengths into the yellow and red portions of the color spectrum. The ability to grow with Indium at higher temperatures leads to a higher quality AlInGaN. This also allows for novel polarization-based band structure designs to create more efficient devices. Additionally, it allows the fabrication of p-GaN layers with increased conductivity, which improves device performance.

### CROSS-REFERENCE TO RELATED APPLICATIONS

This application claims the benefit under 35 U.S.C. Section 119(e) of the following co-pending and commonly-assigned U.S. patent applications:

U.S. Provisional Application Ser. No. 60/866,019 filed on Nov. 15, 2006, by Nicholas A. Fichtenbaum, Umesh K. Mishra and Stacia Keller, entitled “LIGHT EMITTING DIODE AND LASER DIODE USING N-FACE GaN, InN, and AlN AND THEIR ALLOYS” attorneys' docket number 30794.208-US-P1 (2007-204-1);

U.S. Provisional Application Ser. No. 60/866,035 filed on Nov. 15, 2006, by Stacia Keller, Umesh K. Mishra and Nicholas A. Fichtenbaum, entitled “METHOD FOR HETEROEPITAXIAL GROWTH OF HIGH-QUALITY N-FACE GaN, InN, AND AlN AND THEIR ALLOYS BY METAL ORGANIC CHEMICAL VAPOR DEPOSITION,” attorneys' docket number 30794.207-US-P1 (2007-121-1);

which applications are incorporated by reference herein.

This application is related to the following co-pending and commonly-assigned applications:

U.S. patent application Ser. No. 11/523,286, filed on Sep. 18, 2006, by Siddharth Rajan, Chang Soo Suh, James S. Speck, and Umesh K. Mishra, entitled “N-POLAR ALUMINUM GALLIUM NITRIDE/GALLIUM NITRIDE ENHANCEMENT-MODE FIELD EFFECT TRANSISTOR”, attorney's docket number 30794.148-US-U1 (2006-107-2), which claims priority to U.S. Provisional Patent Application Ser. No. 60/717,996, filed on Sep. 16, 2005, by Siddharth Rajan, Chang Soo Suh, James S. Speck, and Umesh K. Mishra, entitled “N-POLAR ALUMINUM GALLIUM NITRIDE/GALLIUM NITRIDE ENHANCEMENT-MODE FIELD EFFECT TRANSISTOR”, attorney's docket number 30794.148-US-P1 (2006-107-1);

U.S. Utility patent application Ser. No. 11/765,629, filed on Jun. 20, 2007 by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH”, attorney's docket number 30794.184-US-U1 (2006-666), which application claims priority under Section 119(e) of U.S. Provisional Patent Application Ser. No. 60/805,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH”, attorney's docket number 30794.184-US-U1 (2006-666);

U.S. Utility patent application Ser. No. 11/768,105, filed Jun. 25, 2007, by Michael Grundmann and Umesh K. Mishra, entitled “POLARIZATION INDUCED TUNNEL JUNCTION”, attorney's docket number 30794.186-US-U1 (2007-668), which application claims priority under Section 119(e) of U.S. Provisional Patent Application Ser. No. 60/815,944, filed on Jun. 23, 2006, by Michael Grundmann and Umesh K. Mishra, entitled “POLARIZATION INDUCED TUNNEL JUNCTION”, attorney's docket number 30794.186-US-P1 (2007-668);

U.S. Utility patent application Ser. No. 11/855,591, filed on Sep. 14, 2007, by Nicholas A. Fichtenbaum, Umesh K. Mishra, and Stacia Keller, entitled “METHOD FOR HETEROEPITAXIAL GROWTH OF HIGH-QUALITY N-FACE GaN, InN, and AlN AND THEIR ALLOYS BY METAL ORGANIC CHEMICAL VAPOR DEPOSITION”, attorney's docket number 30794.207-US-U1 (2007-121-1), which application claims priority under Section 119(e) of U.S. Provisional Patent Application Ser. No. 60/866,035, filed on Nov. 15, 2006, by Nicholas A. Fichtenbaum, Umesh K. Mishra, and Stacia Keller, entitled “METHOD FOR HETEROEPITAXIAL GROWTH OF HIGH-QUALITY N-FACE GaN, InN, and AlN AND THEIR ALLOYS BY METAL ORGANIC CHEMICAL VAPOR DEPOSITION”, attorney's docket number 30794.207-US-P1 (2007-121-1);

U.S. Provisional Patent Application Ser. No. 60/908,904 filed on Mar. 29, 2007, by Umesh K. Mishra, Yi Pei, Siddharth Rajan, and Man Hoi Wong, entitled “N-FACE HIGH ELECTRON MOBILITY TRANSISTORS WITH LOW BUFFER LEAKAGE AND LOW PARASITIC CAPACITANCE”, attorney's docket number 30794.215-US-P1 (2007-269-1);

U.S. Provisional Patent Application Ser. No. 60/908,917, filed on Mar. 29, 2007, by Umesh K. Mishra, Lee S. McCarthy, Chang Soo Suh and Siddharth Rajan, entitled “METHOD TO FABRICATE III-N SEMICONDUCTOR DEVICES ON THE N-FACE OF LAYERS WHICH ARE GROWN IN THE III-FACE DIRECTION USING WAFER BONDING AND SUBSTRATE REMOVAL,” attorney's docket number 30794.216-US-P1 (2007-336-1);

U.S. Provisional Patent Application Ser. No. 60/908,919, filed on Mar. 29, 2007, by Umesh K. Mishra, Michael Grundmann, Steven P. DenBaars, and Shuji Nakamura, entitled “DUAL SURFACE-ROUGHENED N-FACE HIGH-BRIGHTNESS LED,” attorney's docket number 30794.217-US-P1 (2007-279); and

U.S. Provisional Patent Application Ser. No. 60/940,052, filed on May 24, 2007, 2007, by Umesh K. Mishra, Tomas Palacios, and Man Hoi Wong, entitled “POLARIZATION-INDUCED BARRIERS FOR N-FACE NITRIDE-BASED ELECTRONICS,” attorney's docket number 30794.228-US-P1 (2006-648);

which applications are incorporated by reference herein.

### BACKGROUND OF THE INVENTION

1. Field of the Invention

This invention is related to growth of Group III nitride materials, and in particular to Light Emitting Diodes (LEDs) and Laser Diodes (LDs) made from Nitrogen (N) face Gallium Nitride (GaN) Indium Nitride (InN), and Aluminum Nitride (AlN) and their alloys.

2. Description of the Related Art

(Note: This application references a number of different publications as indicated throughout the specification. A list of these different publications can be found below in the section entitled “References.” Each of these publications is incorporated by reference herein.)

The use of group III nitride materials in consumer applications and devices is becoming widespread. However, one of the major challenges to III-Nitride based light emitters is the growth of high quality InGaN. The use of the Gallium (Ga)-face for devices limits the temperature at which the InGaN can be grown, which limits the types of devices that can be made.

It can be seen that additional devices using group III nitrides are desired in the art.

### SUMMARY OF THE INVENTION

The present invention describes light emitting diodes (LEDs) and Laser Diodes (LDs) with improved properties using N-face group III nitride materials.

A light emitting device in accordance with the present invention comprises a p-type group-III nitride, an n-type group-ITT nitride, and a group-III-nitride active region growth along a [000-1] crystal direction resulting in a top surface which is a nitrogen face, wherein a first grown layer of the group III-nitride active region growth is a group III atom layer and a last grown layer of the III-nitride active region growth is a nitrogen layer, such that a spontaneous polarization points towards a growth surface of the III-nitride active region; and the III-nitride active region growth is light emitting and between the n-type nitride and the p-type nitride.

Such a device further optionally comprises the III-nitride active region growth is from a nitrogen face, the III-nitride active region growth is from a group-III-nitride layer, the III-nitride active region is on a misoriented and nitridized substrate, the III-nitride active region growth is a growth from the n-type nitride, the n-type nitride is a growth along a [000-1] direction resulting in a top surface of the n-type nitride which is an N-face, the p-type nitride is a growth from the N-face of the III-nitride active region, the p-type nitride has a magnesium doping greater than 3×10²⁰, the active region contains indium, the III-nitride active region growth contains more indium than an active region which is a growth along a direction resulting in a top surface which is a gallium face, and the III-nitride active region is made from a material selected from the group comprising Nitrogen (N) face Gallium Nitride (GaN), N-face Indium Nitride (InN), and N-face Aluminum Nitride (AlN) and their alloys.

A method for growing a light emitting device in accordance with the present invention comprises growing a light emitting III-nitride active region along a [000-1] crystal direction, resulting in a top surface of the III-nitride active region which is nitrogen-face (N-face).

Such a method further optionally comprises the light emitting III-nitride active region contains indium and is grown at a higher temperature and has an improved surface quality compared to an active region grown along a [0001] direction, growing an n-type nitride along a [000-1] direction and terminating on an N-face of the n-type nitride layer, growing the light emitting III-nitride active region on the N-face of the n-type nitride layer; and growing a p-type nitride layer along a [000-1] direction on the N-face of the light emitting III-nitride active region and terminating on an N-face of the p-type nitride layer, growing an n-type N-face GaN buffer layer on a misoriented and nitridized substrate; growing the light emitting III-nitride active region on the n-type N-face GaN buffer layer, the light emitting III-nitride active region comprising a multiple quantum well region; growing a p-type N-face GaN cap layer on the light emitting III-nitride active region; applying a metal to contact the p-type N-face GaN cap layer; forming one or more light emitting diode mesas by etching the layers obtained in the above steps; and applying a second metal to contact the n-type N-face GaN buffer layer.

The method can further optionally comprise growing an n-type N-face AlGaN buffer and confinement layer, growing an n-type N-face GaN layer on the AlGaN buffer and confinement layer, growing the light emitting III-nitride active region on the n-type N-face GaN layer, the light emitting III-nitride active region comprising multiple quantum wells of InGaN active material, growing a p-type N-face GaN layer on the light emitting III-nitride active region, growing a p-type AlGaN cladding layer on the p-type N-face GaN layer, applying a metal to contact the p-type AlGaN cladding layer, etching a laser diode stripe structure and forming mirror facets into the layers obtained from the above steps, and applying a second metal to contact the n-type N-face GaN layer.

A III-nitride film in accordance with the present invention comprises a growth of III-nitride resulting in a top surface which is a nitrogen face.

Such a film further optionally comprises a first grown layer of the growth is a group III atom layer and a last grown layer of the growth is a nitrogen layer, such that a spontaneous polarization points towards a growth surface of the III-nitride film, the growth is from a misoriented and nitridized surface of a substrate, and the III-nitride film emits light.

### BRIEF DESCRIPTION OF THE DRAWINGS

Referring now to the drawings in which like reference numbers represent corresponding parts throughout:

FIG. 1 illustrates charge profiles for (a) Ga-face and (b) N-face P-I-N structures;

FIG. 2 illustrates band diagrams for Ga-face and N-face multiple quantum well LEDs;

FIG. 3 illustrates a typical LED epitaxial structure;

FIG. 4 illustrates a typical LD epitaxial structure;

FIG. 5 illustrates an LED growth structure and band diagram;

FIG. 6 is a process chart illustrating the process used in fabricating the LED of FIG. 5;

FIG. 7 is a process chart illustrating the process used in an embodiment of the present invention;

FIG. 8 is a process chart illustrating the process used in an embodiment of the present invention.

FIG. 9 is an AFM image of a N-face surface of a GaN film grown by MBE on C-face SiC; and

FIG. 10(a) shows an optical microscope image, and FIG. 10(b) shows an AFM image, of an MOCVD grown GaN N-face film.

FIG. 11 shows an optical image of a prior art N-face III-nitride.

FIG. 12 is an AFM image and photoluminescence data for N-face III-nitride of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention allows the growth of InGaN with greater compositions of Indium than traditionally available now, which pushes LED and LD wavelengths into the yellow and red portions of the color spectrum. The ability to grow with Indium at higher temperatures leads to a higher quality AlInGaN. This also allows for novel polarization-based band structure designs to create more efficient devices. Additionally, it allows the fabrication of p-GaN layers with increased conductivity, which improves device performance.

Technical Description

The present invention allows for the creation of high brightness LEDs and LDs with improved properties. N-face based devices enables the growth of better quality, high Indium composition InGaN alloys which are currently needed to create high power devices in the green, yellow, and red parts of the color spectrum. Additionally, traditional Ga-face GaN suffers from inversion, while N-face doesn't, when doped highly with Mg (e.g., Mg concentrations of approximately 3×10²⁰ which is needed to create p-type GaN). Since high p-type carrier concentrations are a major limitation in nitride based devices, the use of the N-face will drastically increase device performance.

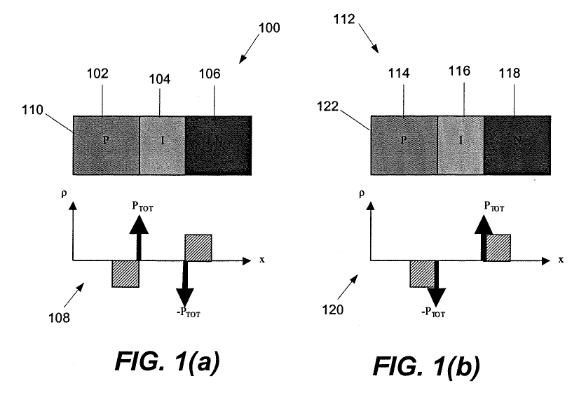

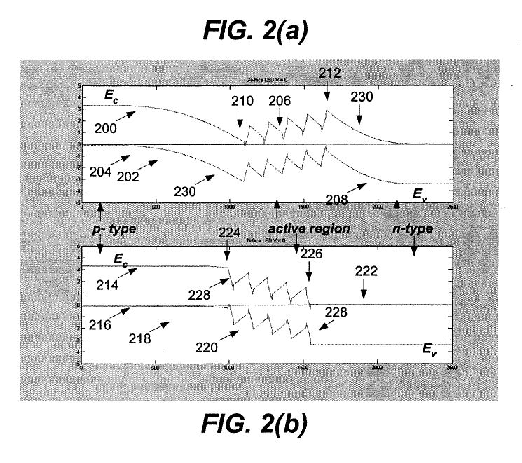

The wurtzite structure of III-Nitrides causes III-Nitrides to exhibit large spontaneous and piezoelectric fields oriented about the [0001] axis. Due to differences in polarization constants, large fixed polarization charges exist at heterostructure interfaces and subsequently electric fields are formed. The direction of these polarization charges and subsequent electric field depends upon the growth direction ([0001] or [000-1]) of the epitaxial film. In the traditional Ga-face LEDs and LDs, the magnitude of the electric field in the quantum well is positive, while in N-face the electric field is negative. For Ga-face this electric field will accelerate carriers past the quantum wells and decrease the efficiency of the devices while the opposite magnitude electric field in N-face will decelerate carriers and increase their capture in quantum wells, thus increasing the efficiency of devices. Additionally, the depletion regions in the structure and thus the turn-on voltage will be different depending upon the polarity of the structure, which is illustrated in FIG. 1 for a simple P-I-N structure and also in FIG. 2 for a LED. In order to achieve N-face growth along the [000-1] direction), the growth substrate typically has a growth surface with a misorientation angle between 0.5 and 10 degrees in any direction relative to a miller indexed crystallographic plane [h, i, k, l] of the substrate, where h, i, k, l are miller indices; and growing the N-face group III-nitride film on the growth surface, wherein the group III-nitride film having an N-face is smoother than an N-face group III-nitride film grown on a substrate without a misorientation angle. The misoriented/viscinal substrate is typically nitridized at medium temperature (approximately 1050° C.).

In the case of a sapphire substrate, the nitridization leads to the formation of an AlN nucleation layer (one or more monolayers thick, for example) on the surface of the sapphire, which sets the N-face polarity of the growth. The nitridization breaks the surface layers of sapphire into AlN. Growth of N-face III-nitride buffer or template can then commence on the AlN nucleation layer(s) terminating the substrate.

Growth of III-nitride on a nitridized misoriented/viscinal substrate at high temperature allows a group III atomic layer to be deposited first and a nitrogen atom layer to be deposited last, yielding an N-face for the III-nitride layer. Subsequent layers grown on the N-face of the first grown III-nitride layer will also be N-face.

The underlying surface on which III-nitride is grown doesn't have to be an N-face to allow the Ga atoms to bond first, it just has to be more attractive (either electrically or mechanically, or both) to the Ga atoms than the N atoms. The N-face is grown last (or formed last) because the Ga-atoms bond better to the nitridized substrate/N-face of the previously-grown layers, which results in a final face of the wurtzite crystal growth being an N-face. The above discussion also holds if the Ga atoms are group III atoms. Further, the definition of N-face or Ga-face is not usually defined by the stacking order (i.e. Ga then N or N then Ga). Typically, the N-face is better defined by the atomic arrangements of the Ga—N bonds, which is encompassed in the direction of the spontaneous polarization of the material. For N-face the spontaneous polarization points towards the surface, while the spontaneous polarization in Ga-face points away from the surface. When N-face is referred to herein, it may refer either to the spontaneous polarization pointing to the surface or the N-atoms residing in the upper layer.

The III-nitride is deposited at medium/high growth temperatures (˜1050° C.—or more typically between 800-1100 C, depending upon the reactor. More details can be found in U.S. Utility patent application Ser. No. 11/855,591, entitled “METHOD FOR HETEROEPITAXIAL GROWTH OF HIGH-QUALITY N-FACE GaN, InN, and AlN AND THEIR ALLOYS BY METAL ORGANIC CHEMICAL VAPOR DEPOSITION, filed Sep. 14, 2007, which application is incorporated by reference herein.

FIG. 1(a) is a schematic showing a PIN structure 100 made from Ga-Face material, comprising a stack of p-type material 102, intrinsic InGaN material 104, and n-type material 106. FIG. 1(a) also shows a graph 108 of charge density ρ as a function of position x across the layers 102, 104, 106 of the PIN 100 structure, wherein x=0 corresponds to the surface 110 of the p-type material. The graph 108 also shows the polarization (P_{TOT}) at the interface between the p-type material 102 and intrinsic InGaN material 104 is positive and P_{TOT} at the interface between the n-type material 106 and intrinsic material 104 is negative.

FIG. 1(b) is a schematic showing a PIN structure 112 made from N-Face material, comprising a stack of p-type material 114, intrinsic InGaN material 116, and n-type material 118. FIG. 1(a) also shows a graph 120 of charge density ρ as a function of position x across the layers 114-118 of the PIN 112 structure, wherein x=0 corresponds to the surface 122 of the p-type material. The graph 120 also shows the P_{TOT} at the interface between the p-type material 114 and intrinsic material 116 is negative and P_{TOT} at the interface between the n-type material 118 and intrinsic InGaN material 116 is positive.

FIG. 2(a) is a band diagram for an unbiased (V=0) light emitting diode made from Ga-Face material, showing the conduction band energy 200 (E_{c}) and valence band energy 202 (Eᵥ) in p-type material 204, in the active region (comprising InGaN/GaN multi quantum wells) 206, and the n-type material 208. The band energy 200,202 in the active region 206 increases from the interface 210 with the p-type material towards the interface 212 with the n-type material (positive gradient), meaning that the electric field in the active region is positive.

FIG. 2(b) is a band diagram for an unbiased (V=0) light emitting diode made from N-Face material, showing the conduction band energy 214 (E_{c}) and valence band energy (Eᵥ) 216 in the p-type material 218, active region 220 (comprising InGaN/GaN multi quantum wells), and n-type material 222. The band energy 214, 216 in the active region 220 decreases from the interface 224 (with the p-type material) towards the interface 226 (with the n-type material), meaning the electric field in the active region 220 is negative.

FIGS. 2(a) and 2(b) also show a decreased depletion width at the interfaces 224, 226 (and consequently decreased turn on voltage for N-face grown GaN devices as compared to Ga-face grown GaN). The decreased depletion width is evidenced by the more abrupt (vertical) band 228 gradient for the N-face grown GaN as compared to the less abrupt (lower) band gradient Ga-face grown GaN 230.

While the production of Ga-face LEDs and LDs in the III-nitride system is widely reported by companies and also universities, growth of a N-face LED or LD has not yet been reported. In the past, growth of N-face by metalorganic chemical vapor deposition lagged significantly behind Ga-face growth in crystal quality, which is the likely reason that there are not reports of light emitters. N-face growth of III-nitrides has been successfully achieved by molecular beam epitaxy (MBE), however the optical quality of the material is still poor, i.e., the efficiency of the device is far less than state of the art Ga-face devices. Currently, the performance of LEDs in the yellow and red part of the spectrum is poor, while laser diodes emitting in the green have not been achieved.

Light Emitting Diode

The LED aspect of this invention is realized by:

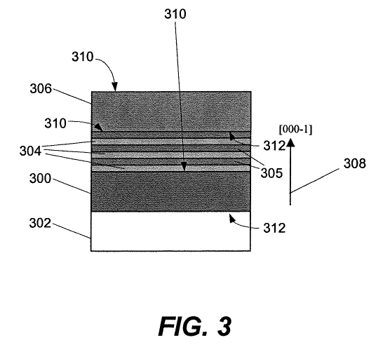

### 1) Growth (typical structure shown in FIG. 3):

a) Growth of a n-type N-face GaN buffer layer 300 on a substrate 302.
b) An optional AlGaN hole blocking layer can be added.
c) The active region is then typically grown, which will comprise of multiple quantum wells of InGaN active material. The quantum wells comprise InGaN 304 and GaN 305 material.
d) An optional AlGaN current blocking layer can then be added.
e) Growth of a p-type N-face GaN cap layer 306.

The arrow 308 indicates the growth direction [000-1], such that the final growth surface 310 of each layer 300-306 is an N-face, and the first growth surface 312 of each layer 300, 304, and 306 is a Ga face or group III atom face. Thus, a first grown layer of the III-nitride active region growth, n-type nitride, and p-type nitride is a group III atom layer and a last grown layer of the III-nitride active region, n-type nitride, or p-type nitride growth is a nitrogen layer. In Ga polar [0001] growth (or ITT-face growth), the surface 310 is Ga face (or a face of group III material) and the surface 312 is N-face. As is known in the art, growth of group III-nitride material comprises alternating layers of group III atoms and nitrogen atoms, with equal numbers of group III layers and nitrogen layers. Thus, for example, a GaN layer comprises equal numbers one or more Ga layers alternating with the same number of nitrogen layers, or again, has a spontaneous polarization pointing toward the surface for the N-faces and a spontaneous polarization pointing away from the surface for the Ga-faces.

### 2) Processing:

a) An appropriate metal is applied to contact the p-type layer 306.
b) LED mesas are formed by etching.
c) An appropriate metal is deposited to contact the n-type layers 300.

Laser diode (LD)

The LD aspect of this invention is realized by:

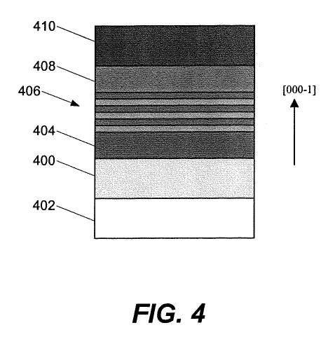

### 1) Growth (typical structure shown in FIG. 4):

a) n-type N-face AlGaN buffer and confinement layer 400 on a substrate 402.
b) N-type N-face GaN layer 404.
c) Active region 406 comprising multiple quantum wells of InGaN active material.
d) P-type N-face GaN layer 408.
e) P-type AlGaN cladding layer 410.

### 2) Processing:

a) An appropriate metal is applied to contact the p-type layer 410
b) LD stripe structure and mirror facets are etched.
c) An appropriate metal is applied to contact the n-type layer 400.

Currently, the growth method being used is MOCVD, however this invention can also be used with other growth methods, for example MBE, HVPE, CBE, etc.

N-Face LED with Tunnel Junction

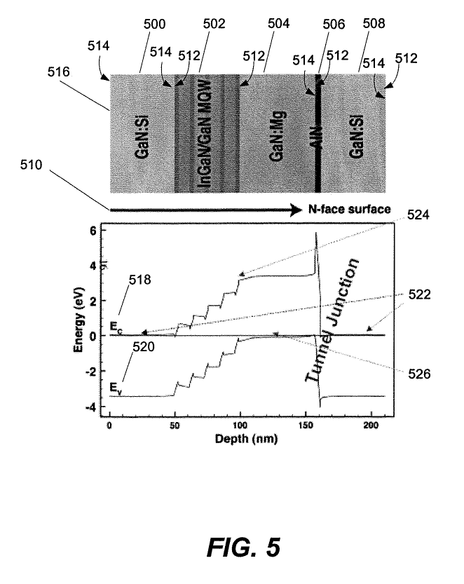

FIG. 5(a) illustrates a schematic of a growth structure of an N-face LED with tunnel junction. The LED comprises an Si doped GaN layer 500, an InGaN/GaN multi quantum well active region 502, an Mg doped GaN layer 504, an AlN layer 506 and an Si doped GaN layer 508. The AlN layer 506 forms a tunnel junction between the GaN layers 504 and 508. The arrow 510 in FIG. 5(a) shows the growth direction and the orientation of the N-face surface, and therefore indicates that the last growth surface of each layer 500-508 is an N-face surface 512. The first growth surface of each layer is therefore a Ga surface (or group III atom surface) 514. In conventional Ga [0001] growth, the surface 512 is a Ga face and the surface 514 is an N-face.

FIG. 5(b) is a band diagram of the structure shown in FIG. 5(a), as a function of depth through the layers 500-508, wherein depth=0 is the surface 516 of the n-type GaN layer 500. Specifically, the band diagram plots the conduction band energy E_{C} 518 and the valence band energy E_{V} 520. The band diagram shows E_{C}˜0 522 in the n-type layers 500, 508, evidencing all n-type contact to the LED. The all n-type contacts are possible due to the polarization induced tunnel junction whose energy is also shown in FIG. 5(b). The large gradient of the band profile 524 at the interface between the active region 502 and the p-type layer 504 evidences a narrow depletion region. Finally, E_{V}˜0 526 in the thin p-type layer 504 evidences reduced series resistance for the device.

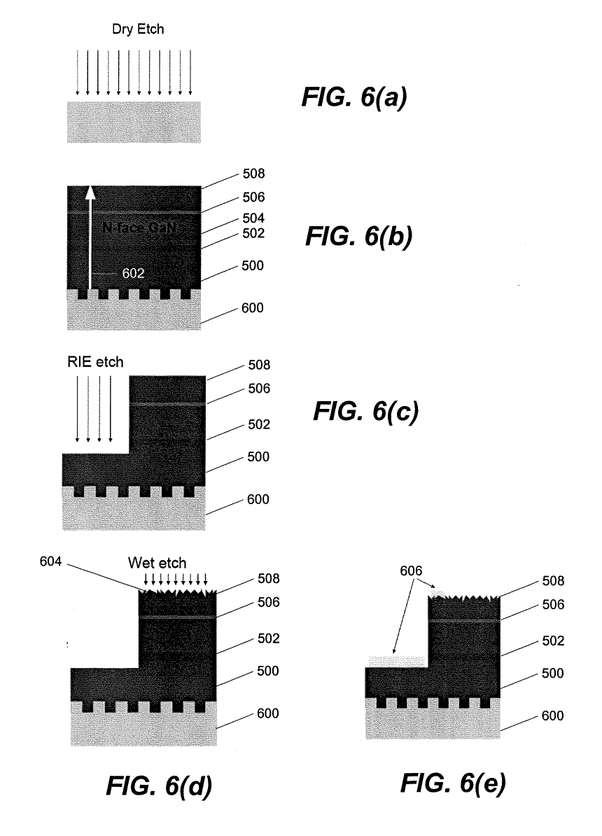

FIGS. 6(a)-(e) illustrate a method of fabricating an N-face LED with tunnel junction.

FIG. 6(a) illustrates the step of preparing the surface of the sapphire substrate, for example, pre-patterning a sapphire substrate by a dry etch to form a patterned sapphire surface (PSS) 600.

FIG. 6(b) illustrates the step of growing the layers 500-508 sequentially in the N-face direction 602.

FIG. 6(c) illustrates the step of etching a mesa using a reactive ion etch (RIE) etch.

FIG. 6(d) illustrates the step of wet etching the Si doped GaN layer 508 (the base of the LED) in order to roughen the top surface 604 of the Si GaN layer 508. The roughened surface 604 enhances light extraction from the LED.

FIG. 6(e) illustrates the step of forming n-type ohmic contacts 606 on the layers 508 and 500.

Possible Modifications

Any appropriate substrate can be used, such as SiC, Si, spinel, bulk GaN, ZnO, etc., as long as N-face GaN can be grown.

The epitaxial structure described with InGaN as the active material and also the corresponding confinement and buffer layers can be changed to use GaN, AlGaN, or AlInGaN—depending upon the desired wavelength of emission.

The structure can be grown with p-type first followed by an active region and n-type as long as the polarity is still N-face.

The layer thicknesses and compositions can be varied appropriately.

The LD can be grown appropriately to create a vertical cavity surface emitting laser (VCSEL) with the addition of distributed Bragg reflectors (DBR) above and below the active region.

The LED structure can be grown upon a DBR to enhance light extraction.

Light extraction methods can be applied to the LED such as ZnO megacones or surface roughening.

Other non (Al,Ga,In)N layers can be inserted for stress and threading dislocation management.

The discussion of Ga-face growth throughout this disclosure also applies to group III atom growth along the [0001] direction.

The present invention describes a light emitting device, comprising p-type nitride, n-type nitride, and an active region between the p-type nitride and the n-type nitride, wherein the active region is a growth of nitride along a [000-1] crystal direction terminating with a nitrogen face. The p-type layer, n-type layer, and active layer may have any composition or structure known in the art suitable for use in a III-nitride (or III-nitride alloy comprising (Al, In, Ga)N, for example) based light emitting diode or laser diode. Therefore, the active layer is not limited to quantum wells. Moreover, additional layers as are known in the art may also be included, for example, current spreading layers, contacts layers etc.

Process Chart

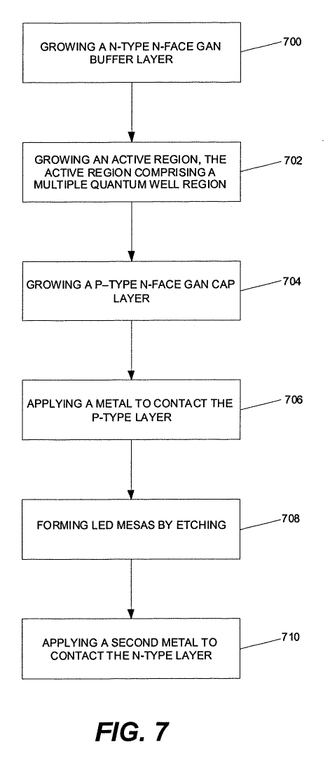

FIG. 7 is a process chart illustrating the process used in an embodiment of the present invention.

For an LED, a typical process chart is as follows.

Box 700 illustrates growing a n-type N-face GaN buffer layer on a substrate.

Box 702 illustrates growing an active region, the active region comprising a multiple quantum well region.

Box 704 illustrates growing a p-type N-face GaN cap layer.

Box 706 illustrates applying a metal to contact the p-type layer.

Box 708 illustrates forming LED mesas by etching.

Box 710 illustrates applying a second metal to contact the n-type layers.

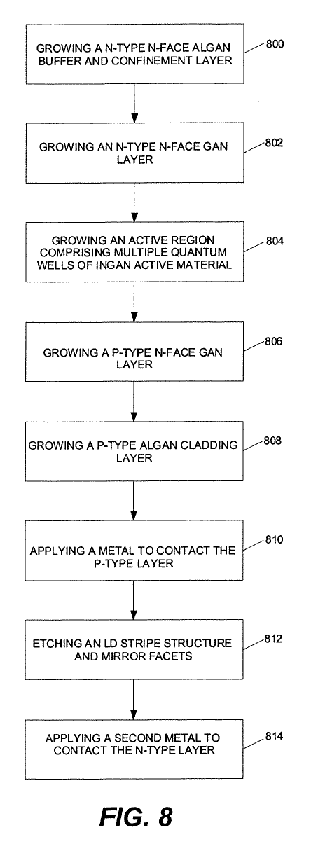

For a Laser Diode, a typical process chart is as follows (as shown in FIG. 8).

Box 800 illustrates growing a N-type N-face AlGaN buffer and confinement layer on a substrate.

Box 802 illustrates growing an N-type N-face GaN layer.

Box 804 illustrates growing an active region comprising multiple quantum wells of InGaN active material.

Box 806 illustrates growing a P-type N-face GaN layer.

Box 808 illustrates growing a P-type AlGaN cladding layer.

Box 810 illustrates applying a metal to contact the p-type layer.

Box 812 illustrates etching an LD stripe structure and mirror facets.

Box 814 illustrates applying a second metal to contact the n-type layer.

The various layers are grown at temperatures appropriate to control the desired alloy composition of the particular layer.

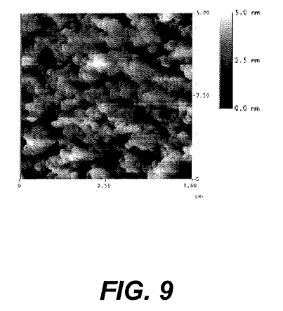

The present invention also allows the growth of III-nitride N-face films. The films can be grown using a variety of growth methods, including but not limited to Molecular Beam Epitaxy (MBE) and Metal Organic Chemical Vapor Deposition (MOCVD). FIG. 9 shows N-face surface AFM image of a GaN film grown by MBE on C-face SiC. The growth temperature was 710-720° C., and the dislocation reduction was achieved using a two step buffer, wherein in step 1 GaN growth was initiated on the SiC with a Ga flux in a low to intermediate regime and in step 2 morphology was recovered by increasing the Ga flux. This method achieved a threading dislocation density of ˜10¹⁰ cm⁻², and a surface roughness of at most 5 nm in a 5 micron by 5 micron area. The film was doped with Si to at least 3×10¹⁸ cm⁻³ to achieve a mobility of at least 140 cm²/Vs, which is comparable to Ga-face MBE grown films. However, N-face p-type films have increased surface stability when they are doped with high (>1×10²⁰) Mg concentrations. These films could be used as substrates or devices, such as electronic (transistors) or optoelectronic devices.

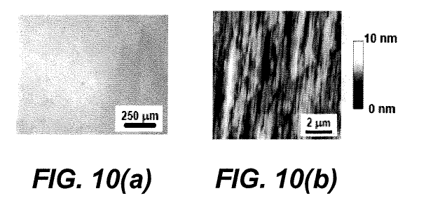

FIG. 10(a) shows an optical microscope image, and FIG. 10(b) shows an AFM image, of an MOCVD grown GaN N-face film, showing rms roughness of at most 0.9 nm. XRD measurements of these 1-1.5 micron thick GaN films measured FWHM (along the 002 reflection) of at most 110 arcsecs and FWHM (along the 201 reflection) of at most 900 arcsecs for a misorientation of 2 degrees towards the sapphire A direction, and FWHM (along the 002 reflection) of at most 300 arcsecs and FWHM (along the 201 reflection) of at most 450 arcsecs for a misoreintation of four degrees toward the sapphire A direction.

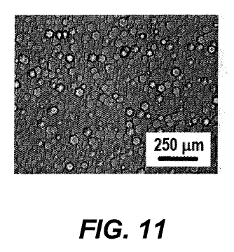

FIG. 11 shows the poor surface morphology of prior art N-face growth. For example, prior art growth by MOCVD has been typically rough due to formation of hexagonal hillocks (having micron sized dimensions), observed for hetero-epitaxial and homoepitaxial growth of GaN. This poor surface morphology has prevented application for devices.

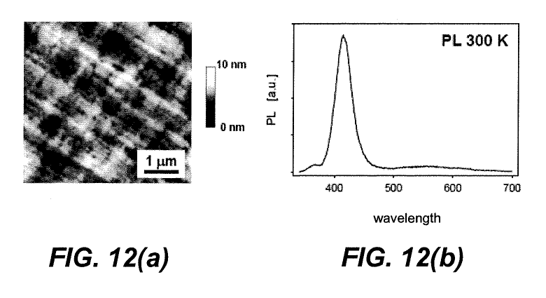

FIG. 12(a) shows an AFM image of InGaN/GaN multi quantum wells (MQWs) grown using the present invention, where the RMS roughness is 0.85 nm, showing a smooth surface at InGaN growth temperatures. FIG. 12(b) shows 300 Kelvin photoluminescence (PL) of MQWs comprising 5×(3 nm thick In_{0.1}Ga_{0.9}N/8 nm thick GaN), grown by MOCVD according to the present invention. The photoluminescence is intense in the range 385 nm to 475 nm.

The N-face III-nitride grown using the present invention has increased optical quality and increased structural or surface quality. The increased structural or surface quality (characterized by reduced surface roughness, smaller XRD diffraction FWHM's, reduced threading dislocation), as compared to N-face III-nitride grown using prior art techniques. The increased optical quality is evidenced by the fact that prior art methods have not achieved adequate light emission whereas the present invention has higher emission efficiency in these regions.

Advantages and Improvements

One of the major challenges to III-Nitride based light emitters is the growth of high quality InGaN. N-face allows the growth of InGaN at higher temperatures than the traditional Ga-face, which will provide better quality material as well as making higher indium content films feasible, where indium content films are now more stable at any concentration of indium in the InGaN material. For example, the growth temperature for MBE grown InN is approximately 100° C. higher for N-face growth as compared to Ga-face growth.

Another challenge to the growth of light emitters is p-type doping. In the traditional Ga-face material, too much p-type doping (Mg) causes the surface to invert to N-face in places causing a poor quality film. However, N-face does not seem to suffer a similar fate with p-type doping, allowing higher levels of p-type doping, which will create much better device performance.

III-nitride based light emitters suffer from strong polarization induced electric fields. N-face material provides an electric field in the opposite direction to the traditional Ga-face which allows for lower turn-on voltages and also increased quantum efficiencies.

The etching properties of N-face are distinctly different from that of Ga-face which will be useful in creating better light extraction schemes in LEDs, such as surface roughening, and mega-cones.

N-face devices can be obtained by growing a nitride device in the Ga (0001) direction and removing the substrate to expose the N-Face of the device. However, this process is more difficult (and consequently more expensive and time consuming) than the present invention because it involves the additional step of substrate removal.

It is possible to characterize whether an N-face device has been grown using the present invention or by growing in the Ga polar direction [0001] followed by substrate removal to expose the N-face:
a) The present invention grows a light emitting device on a misoriented or miscut substrate. The miscut shows in subsequent layers grown on the miscut substrate. The misorientation is transferred to layers grown on top of the buffer layer, all of which can be measured by x-ray diffraction. It is unlikely that a device grown along the [0001] Ga polar direction would be grown on a miscut substrate because this would lead to a decreased smoothness of the epitaxially grown layers.
b) The active region in a device grown using the present invention will typically have a higher oxygen concentration as compared to the active region grown in a Ga-polar (0001) direction.
c) In order to achieve a device where the p-type layer is on an N-face nitride layer, the present invention may grow the p-type layer before or after the n-type layer and active layer. However, using the conventional (0001) Ga polar growth, the p-type layer would have to be grown before the n-type layer and active layer. The order in which the layers have been grown can also be measured by measuring impurity concentrations and structural quality of the various layers. Growing a p-type layer first generally leads to poor material on top because of the use of high Mg doping concentrations, which creates defects.

### REFERENCES

The following references are incorporated by reference herein:
[1] Homo-epitaxial GaN growth on exact and misoriented single crystals: suppression of hillock formation: A. R. A. Zauner, J. L. Weyher, M. Plomp, V. Kirilyuk, I. Grzegory, W. J. P. van Enckevort, J. J. Schermer, P. R. Hageman, and P. K. Larsen, J. Cryst. Growth 210 (2000) 435-443.
[2] Homo-epitaxial GaN growth on the N-face of GaN single crystals: the influence of the misorientation on the surface morphology: A. R. A. Zauner, A. Aret, W. J. P. van Enckevort, J. L. Weyher, S. Porowski, J. J. Schermer, J. Cryst. Growth 240 (2002) 14-21.
[3] A. P. Grzegorczyk et al. Influence of sapphire annealing in trimethylgallium atmosphere on GaN epitaxy by MOCVD: J. Cryst. Growth 283 (2005) 72-80.
[4] N-polarity GaN on sapphire substrates grown by MOCVD: T. Matsuoka, Y. Kobayashi, H. Takahata, T. Mitate, S Mizuno, A. Sasaki, M. Yoshimoto, T. Ohnishi, and M. Sumiya, phys. stat. sol. (b) 243 (2006) 1446-1450.
[5] The effect of substrate polarity on the growth of InN by RF-MBE: Naoi et al., J. Cryst. Growth 269 (2004) 155-161.
[6] S. Keller, et al., Growth and Characterization of n-polar InGaN/GaN Multiquantum Wells. Applied Physics Letters 90, 191908 (2007).
[7] S. Keller, et al., Influence of the substrate misorientation on the properties of N-polar GaN films grown by metal organic chemical vapor deposition. Applied Physics Letters 102, 083546 (2007).
[8] N. A. Fichtenbaum, et al., Electrical characterization of p-type N-polar and Ga-polar GaN grown by metalorganic chemical vapor deposition. Applied Physics Letters 91, 172105 (2007).

### CONCLUSION

This concludes the description of the preferred embodiment of the present invention. The present invention describes III-nitride films, light emitting devices and methods for making light emitting devices and III-nitride films.

These techniques, growth methods, and device structures can also be applied to other electronic devices, such as solar cells, photodetectors, transistors, and other electronic devices that use Group III nitride material systems.

A light emitting device in accordance with the present invention comprises a p-type group-III nitride, an n-type group-ITT nitride, and a group-III-nitride active region growth along a [000-1] crystal direction resulting in a top surface which is a nitrogen face, wherein a first grown layer of the group III-nitride active region growth is a group III atom layer and a last grown layer of the III-nitride active region growth is a nitrogen layer, such that a spontaneous polarization points towards a growth surface of the III-nitride active region; and the III-nitride active region growth is light emitting and between the n-type nitride and the p-type nitride.

Such a device further optionally comprises the III-nitride active region growth is from a nitrogen face, the III-nitride active region growth is from a group-III-nitride layer, the III-nitride active region is on a misoriented and nitridized substrate, the III-nitride active region growth is a growth from the n-type nitride, the n-type nitride is a growth along a [000-1] direction resulting in a top surface of the n-type nitride which is an N-face, the p-type nitride is a growth from the N-face of the III-nitride active region, the p-type nitride has a magnesium doping greater than 3×10²⁰, the active region contains indium, the III-nitride active region growth contains more indium than an active region which is a growth along a direction resulting in a top surface which is a gallium face, and the III-nitride active region is made from a material selected from the group comprising Nitrogen (N) face Gallium Nitride (GaN), N-face Indium Nitride (InN), and N-face Aluminum Nitride (AlN) and their alloys.

A method for growing a light emitting device in accordance with the present invention comprises growing a light emitting III-nitride active region along a [000-1] crystal direction, resulting in a top surface of the III-nitride active region which is nitrogen-face (N-face).

Such a method further optionally comprises the light emitting III-nitride active region contains indium and is grown at a higher temperature and has an improved surface quality compared to an active region grown along a [0001] direction, growing an n-type nitride along a [000-1] direction and terminating on an N-face of the n-type nitride layer, growing the light emitting III-nitride active region on the N-face of the n-type nitride layer; and growing a p-type nitride layer along a [000-1] direction on the N-face of the light emitting III-nitride active region and terminating on an N-face of the p-type nitride layer, growing an n-type N-face GaN buffer layer on a misoriented and nitridized substrate; growing the light emitting III-nitride active region on the n-type N-face GaN buffer layer, the light emitting III-nitride active region comprising a multiple quantum well region; growing a p-type N-face GaN cap layer on the light emitting III-nitride active region; applying a metal to contact the p-type N-face GaN cap layer; forming one or more light emitting diode mesas by etching the layers obtained in the above steps; and applying a second metal to contact the n-type N-face GaN buffer layer.

The method can further optionally comprise growing an n-type N-face AlGaN buffer and confinement layer, growing an n-type N-face GaN layer on the AlGaN buffer and confinement layer, growing the light emitting III-nitride active region on the n-type N-face GaN layer, the light emitting III-nitride active region comprising multiple quantum wells of InGaN active material, growing a p-type N-face GaN layer on the light emitting III-nitride active region, growing a p-type AlGaN cladding layer on the p-type N-face GaN layer, applying a metal to contact the p-type AlGaN cladding layer, etching a laser diode stripe structure and forming mirror facets into the layers obtained from the above steps, and applying a second metal to contact the n-type N-face GaN layer.

A III-nitride film in accordance with the present invention comprises a growth of III-nitride resulting in a top surface which is a nitrogen face.

Such a film further optionally comprises a first grown layer of the growth is a group III atom layer and a last grown layer of the growth is a nitrogen layer, such that a spontaneous polarization points towards a growth surface of the III-nitride film, the growth is from a misoriented and nitridized surface of a substrate, and the III-nitride film emits light.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the exemplary claims appended hereto and the full range of equivalents to the exemplary claims appended hereto.

What is claimed is:

1. A light emitting device, comprising:
(a) a p-type group-ITT nitride;
(b) an n-type group-III nitride; and
(c) a group-III-nitride active region growth along a [000-1] crystal direction resulting in a top surface which is a nitrogen face, wherein
(1) a first grown layer of the group-III-nitride active region growth is a group III atom layer and a last grown layer of the group-III-nitride active region growth is a nitrogen layer, such that a spontaneous polarization points towards a growth surface of the III-nitride active region; and
(2) the group-III-nitride active region growth is light emitting and between the n-type nitride and the p-type nitride.

2. The light emitting device of claim 1, wherein the group-III-nitride active region growth is from a nitrogen face.

3. The light emitting device of claim 2, wherein the group-III-nitride active region growth is from a group-III-nitride layer.

4. The light emitting device of claim 1, wherein the group-III-nitride active region is on a misoriented and nitridized substrate.

5. The light emitting device of claim 1, wherein the group-III-nitride active region growth is a growth from the n-type nitride.

6. The light emitting device of claim 1, wherein the n-type nitride is a growth along a [000-1] direction resulting in a top surface of the n-type nitride which is an N-face.

7. The light emitting device of claim 1, wherein the p-type nitride is a growth from the N-face of the group-III-nitride active region.

8. The light emitting device of claim 7, wherein the p-type nitride has a magnesium doping greater than 3×10²⁰.

9. The light emitting device of claim 1, wherein the active region contains indium.

10. The light emitting device of claim 9, wherein the group-III-nitride active region growth contains more indium than an active region which is a growth along a [0001] direction resulting in a top surface which is a gallium face.

11. The light emitting device of claim 1, wherein the group-III-nitride active region is made from a material selected from the group comprising Nitrogen (N) face Gallium Nitride (GaN), N-face Indium Nitride (InN), and N-face Aluminum Nitride (AlN) and their alloys.

12. A method for growing a light emitting device, comprising
growing a light emitting III-nitride active region along a [000-1] crystal direction, resulting in a top surface of the III-nitride active region which is nitrogen-face (N-face).

13. The method of claim 12, wherein the light emitting III-nitride active region contains indium and is grown at a higher temperature and has an improved surface quality compared to an active region grown along a [0001] direction.

14. The method of claim 12, further comprising:
(a) growing an n-type nitride along a [000-1] direction and terminating on an N-face of the n-type nitride layer,
(b) growing the light emitting III-nitride active region on the N-face of the n-type nitride layer; and
(c) growing a p-type nitride layer along a [000-1] direction on the N-face of the light emitting III-nitride active region and terminating on an N-face of the p-type nitride layer,

15. The method of claim 12, further comprising:
(a) growing an n-type N-face GaN buffer layer on a misoriented and nitridized substrate;
(b) growing the light emitting III-nitride active region on the n-type N-face GaN buffer layer, the light emitting III-nitride active region comprising a multiple quantum well region;
(c) growing a p-type N-face GaN cap layer on the light emitting III-nitride active region;
(d) applying a metal to contact the p-type N-face GaN cap layer;
(e) forming one or more light emitting diode mesas by etching the layers obtained in steps (a)-(e); and
(f) applying a second metal to contact the n-type N-face GaN buffer layer.

16. The method of claim 12, further comprising:
(a) growing an n-type N-face AlGaN buffer and confinement layer;
(b) growing an n-type N-face GaN layer on the AlGaN buffer and confinement layer;
(c) growing the light emitting III-nitride active region on the n-type N-face GaN layer, the light emitting III-nitride active region comprising multiple quantum wells of InGaN active material;
(d) growing a p-type N-face GaN layer on the light emitting III-nitride active region;
(e) growing a p-type AlGaN cladding layer on the p-type N-face GaN layer;
(f) applying a metal to contact the p-type AlGaN cladding layer;
(g) etching a laser diode stripe structure and forming mirror facets into the layers obtained from steps (a)-(g); and
(h) applying a second metal to contact the n-type N-face GaN layer.

17. A III-nitride film, comprising:
a growth of III-nitride resulting in a top surface which is a nitrogen face.

18. The III-nitride film of claim 17, wherein a first grown layer of the growth is a group III atom layer and a last grown layer of the growth is a nitrogen layer, such that a spontaneous polarization points towards a growth surface of the III-nitride film.

19. The III-nitride film of claim 17, wherein the growth is from a misoriented and nitridized surface of a substrate.

20. The III-nitride film of claim 17, wherein the III-nitride film emits light.
